(19) United States
(12) Patent Application Publication
(10) Pub. No.: US 2008/0038464 A1
(43) Pub. Date: Feb. 14, 2008

(54) Methods for Coating a Substrate and Forming a Colored Film and Related Device

(75) Inventors: Jean Durand, Montpellier (FR); Francois Lauvray, Paris (FR); Isabelle Richardt, Vanves (FR)

Correspondence Address: MATTHEW R. JENKINS, ESQ., 2310 FAR HILLS BUILDING, DAYTON, OH, 45419, US

(73) Assignee: NEYCO, Paris (FR)

(21) Appl. No.: 10/599,691

(22) PCT Filed: Apr. 1, 2005
(86) PCT No.: PCT/FR05/00798

§ 371 Date: Apr. 27, 2007

(30) Foreign Application Priority Data
Apr. 6, 2004 (FR) 0403592

(51) Int. Cl. C23C 16/50; C23C 16/00; C23C 16/22

(52) U.S. Cl. 427/255.29; 118/715; 118/723 R; 427/255.28

(57) ABSTRACT

A method comprising the following steps: placing the substrates in an evacuated enclosures; forming a gas by evaporating a component that is liquid at atmospheric pressure and at ambient temperature; and introducing the gas into the enclosure. The gas is decomposed and a complementary gas is introduced into the enclosure for the purpose of reacting with the decomposed gas so as to form at least one thin layer on the substrate. Also disclosed is a method of forming a colored film and to an associated device capable of implementing the method of the invention.

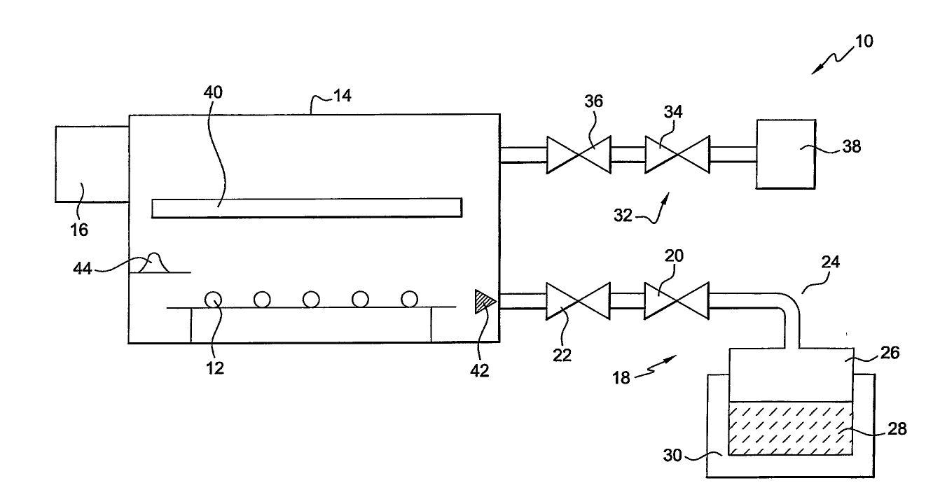

The present invention relates to methods of coating a substrate and of forming a coloured film, and also to an associated device.

The invention applies more particularly to coating a substrate made of plastics material or of glass, e.g. for the automobile, ophthalmological, or glassmaking industries.

In the state of the art, a method of coating a substrate is already known that is of the type comprising:

placing the substrate in an enclosure under vacuum;

introducing a gas into the enclosure; and

decomposing the gas to form at least a first thin layer on the substrate.

It is known to create the gas inside the enclosure by heating a solid component therein, e.g. an aluminum wire, until the component evaporates. The vapour which deposits on the substrate then forms of the desired thin layer. Nevertheless, that method is not advantageous economically speaking, since it requires heating to a high temperature (e.g. with an aluminum wire, it is necessary to heat to a temperature of 1100° C.).

It is also known for the gas that is introduced into the enclosure to be a component coming from a receptacle in which it is stored in the liquid phase under pressure. The liquid component is expanded in order to be introduced in the gaseous phase into the enclosure. Such a component is difficult to handle, in particular because of its toxicity and because of the sealing problems it raises.

Finally, it is known to introduce the gas into the enclosure by evaporating a component that is liquid at ambient temperature and at atmospheric pressure. Practically no liquid component is lost during the coating process and the liquid component is easy to handle. Nevertheless, the thin film obtained by evaporating the liquid component is generally fragile and not very hard.

After the coating has been deposited, the substrate is usually extracted from the enclosure in order to be covered in a protective layer by spraying a varnish thereon under atmospheric pressure.

In general, those two steps are preceded by a step of coating the substrate in a layer for smoothing the surface of the substrate and/or a keying layer for bonding to subsequent layers. The layers of this optional step are likewise obtained by spraying a varnish thereon under atmospheric pressure.

Thus, certain plastics stoppers for perfume bottles are conventionally coated in three layers: a keying layer of bonding varnish; a thin layer of metalization, deposited under a vacuum from aluminum wire, for example; and a layer of varnish providing protection against oxidation.

A particular object of the invention is to reduce the cost of the above-described coating method and to optimise implementation of the method.

To this end, the invention provides method of coating a substrate, the method being the type comprising:

placing the substrate in an evacuated enclosure;

forming a gas by evaporating a component that is liquid at atmospheric pressure and at ambient temperature;

introducing the gas into the enclosure; and

decomposing the gas;

the method being characterised by introducing a complementary gas into the enclosure for the purpose of reacting with the decomposed gas so as to form, on the substrate, at least one thin layer, referred to as thin layer A.

The gaseous component that results from the reaction between of the decomposed gas and the complementary gas forms, on the substrate, a thin layer having the property of being relatively hard.

Optionally, a method of coating a substrate of the invention comprises a step of forming, on the substrate, another thin layer, referred to as thin layer B, by carrying out vacuum deposition in the enclosure before or after forming the thin layer A.

The thin layer A is relatively hard and possesses properties that are equivalent to, and sometimes better than, the properties of the thick layers of varnish as used in the past. Thus, depositing the thin layer A of the invention enables the thin layer B, the “working” layer, to be deposited and/or protected, by replacing the prior art layer of smoothing, bonding, or protective varnish.

A method of the invention for coating a substrate may also comprise one or more of the following characteristics:

the component is made up of organic and inorganic groups, e.g. of silicone;

the complementary gas is monomolecular up to at least 90%;

the complementary gas comprises, for the most part, either dioxygen, or argon, or dinitrogen, or dihydrogen, or acetylene;

the gas is decomposed with the help of electric plasma-creation means;

the thin layers A and B are formed without extracting the substrate from the enclosure between forming each layer;

the thin layer A is formed after each thin layer B in such a manner as to cover said thin layer B, in particular in order to provide it with mechanical and/or chemical protection;

the thin layer B is formed after the thin layer A in such a manner that said thin layer A encourages smoothing the substrate and/or bonding the thin layer B;

the thin layer B is a layer of metalization;

the layer of metalization is formed by evaporating a solid component; and

the layer of metalization is formed by evaporating an organometallic component that is in the liquid phase at ambient temperature and at atmospheric pressure.

The invention also provides a method of forming a coloured film on a substrate, the method being the type in which at least two thin layers having different refractive indices are deposited on the substrate, the method being characterised in that at least one of the thin layers is obtained by a coating method of the invention.

The invention also provides a device for implementing a method of coating a substrate as defined above, the device being characterised in that it comprises:

an enclosure for housing the substrate;

the tank external to the enclosure for containing a liquid component;

first admission means for admitting a gas into the enclosure and comprising means for connecting the enclosure to a portion of the tank containing a vapour phase of the gas-forming liquid;

means for decomposing the gas; and

second admission means for admitting a complementary gas for reacting with the decomposed gas.

A coating device of the invention may also comprise one or more of the following characteristics:

the admission means include means for adjusting the admission flow rate of the gas;

the gas-decomposition means are electric means for generating a plasma inside the enclosure from the gas; and

the device comprises means for creating a vacuum in the enclosure.

The invention can be better understood on reading the following description given purely by way of example and made with reference to the sole FIGURE which is a diagram of a substrate-coating device implementing a method of the invention.

The sole FIGURE shows a device 10 according to the invention for vacuum coating substrates 12.

The substrates 12 are usually parts made of plastics material or of glass, for example, and in nonlimiting manner:

stoppers for perfume bottles;

door handles;

motor vehicle headlights; and

lenses for eyeglasses.

The device 10 comprises a sealed enclosure 14 in which the substrates 12 are placed.

Conventional means 16 serve to create, and where appropriate to measure, a vacuum inside the enclosure 14. These means 16 enable the pressure inside the enclosure to be reduced to a usual value in the range 1 pascal (Pa) to 10⁻² Pa (secondary vacuum). In this example, the vacuum-creation means 16 comprise a conventional diffusion pump, or any other (turbomolecular, cryogenic) pomp capable of providing a secondary vacuum.

The device 10 further comprises first admission means 18 for admitting a gas into the enclosure 14.

The first admission means 18 comprise a first on/off valve 20 connected in series with a first adjustable-leakage valve, e.g. of the needle type 22, the valve constituting means for adjusting the flow rate of the gas introduced into the enclosure 14.

The first admission means 18 further comprise a duct 24 forming means for connection to a tank 26 external to the enclosure 14. More precisely, the duct 24 connects the enclosure 14 to a portion of the tank 26 that contains a vapour phase of the liquid that forms the gas.

The tank 26 is for containing a liquid component 28 that can be heated by means of heater means 30, e.g. electrical resistor means.

The term “liquid component” 28 is understood to mean a component that is in liquid form at atmospheric pressure and at ambient temperature, i.e. in the range 15° C to 30° C.

It should be observed that the duct 24 connects the enclosure 14 to a portion of the tank 26 that is to contain a vapour phase of the gas-forming component 28.

The device can also comprise a second gas admission means 32 for admitting a complementary gas into the enclosure 14. More precisely, the complementary gas is constituted by a monomolecular gas up to at least 90%.

The second admission means 32 comprise a second on/off valve 34 connected in series with a second adjustable-leakage valve, e.g. of the needle type 36, this valve forming means for adjusting the flow rate of the complementary gas that is introduced into the enclosure 14 for the purpose of reacting with the decomposed gas.

In a variant, the monomolecular gas could be replaced by air. Under such circumstances, the on/off valve 34 is itself connected to the surrounding air via an air filter 38.

The device 10 also comprises means of the generating a plasma inside the enclosure from the gas, the plasma-generation means forming means for decomposing the gas. In the example described, these plasma-generation means comprise a conventional corona bar 40 housed inside the enclosure 14 and designed to be connected to a high direct current (DC) voltage usually lying in the range 1 kilovolt (kV) to 10 kV. In a variant, the bar may be raised to an alternating current (AC) voltage, e.g. 400 volts (V), at high to ultrahigh frequency.

There follows a description of an example of the method of the invention as implemented by the device shown in the FIGURE. It should be observed that this example does not limit the scope of the invention.

In order to coat a substrate 12 that is to form a stopper for a perfume bottle, there are formed on this substrate 12 a first thin layer constituted by silicon dioxide (SiO₂); a second thin layer constituted by aluminum metalization (Al) covering the first; and finally a third thin layer (constituted by SiO₂) covering the second.

The first thin layer encourages smoothing of the substrate and bonding of the second thin layer. The third thin layer provides the second layer that is constituted by metalization with mechanical and/or chemical protection.

These three thin layers are formed during three sequences that are described below, without extracting the substrate 12 from the enclosure 14 between forming each of the layers.

The first sequence of depositing the first thin layer (of SiO₂) is as follows. The substrate is placed inside the enclosure 14 and the atmosphere is evacuated from the enclosure 14 by means of the diffusion pump 16, with the pressure inside the enclosure then reaching 10⁻² Pa. The valves 20 and 30 are closed.

The tank 26 connected to the admission means 18 is filled with the component 28 that is preferably formed by organic and inorganic groups. In the example described, the component is a silicone, more particularly methyl siloxane formed by organic methyl groups and by silica-based inorganic groups, e.g. the silicone sold by the supplier Dow Corning under the trade name DC-200.

This component is heated by the heater means 30 in order to form a gas, and the gas is introduced into the enclosure 14 by opening the valve 20, while adjusting its flow rate by means of the needle valve 22. Connecting the tank 26 to the evacuated enclosure causes the methyl siloxane to evaporate and be admitted into the enclosure 14. A jet-breaker 42 serves to distribute the gas uniformly inside the enclosure.

Thereafter, the gas is decomposed in order to form a plasma. The plasma is obtained by decomposing the molecules of the gas by electric excitation, e.g. by subjecting the gas to a high voltage created under such circumstances by raising the corona bar 40 to a voltage of 3 kV.

By opening the valves 34 and 36, dioxygen is introduced into the enclosure 14 where it constitutes the complementary gas for reacting with the decomposed gas, i.e. with the plasma.

The dioxygen reacts with the plasma, and more particularly with the non stoechiometric compound SiO_{y}, in order to form the first layer of the stoechiometric compound SiO₂ on the substrate 12.

In a variant, instead of using dioxygen, it is possible to use air or any complementary gas that comprises for the most part one of the components in the following non-exhaustive list: argon, dinitrogen, dihydrogen, acetylene, each component causing a thin layer to be formed that is based on a SiOₓ group.

The second sequence of depositing the second thin layer (of metalization) takes place as follows.

The metalization of the second thin layer is made by depositing from the gaseous form of a solid component, which in this example comprises an aluminum wire 44 that is housed in the enclosure 14. The gaseous form of the component 44 is obtained by heating said component 44, e.g. by the Joule effect or by means of an electron gun.

In a variant, this layer of metalization can be formed by using a sequence analogous to that of the first sequence, by using an organometallic liquid component and without using any complementary gas.

The third sequence of depositing the third thin layer (of SiO₂) is analogous to the sequence of depositing the first layer.

If it is desired to color the substrate 12 before depositing the third thin layer as described above, then the substrate 12 is coated in a coloured film comprising at least two thin layers having different refractive indices, at least one of the thin layers being obtained by using a sequence analogous to the first sequence of the method, but with a different liquid component.

The coloured film thus generally comprises about fifteen thin layers all formed using a sequence analogous to the first sequence of the method, alternating layers formed from methyl siloxane with layers formed from titanium isopropoxide. Selecting the thickness of the layers serves to give the substrate the desired color, by causing certain frequencies of incident light rays to be absorbed by the multi-layer film.

The last layer of the stack is preferably obtained from methyl siloxane, and forms the protective third layer.

The enclosure is preferably cleaned between each thin layer deposition sequence, by recreating a secondary vacuum inside the enclosure. In a variant, the enclosure may be cleaned by a flushing effect by pumping out the gases contained inside the enclosure while introducing an inert gas into the enclosure.

It should be observed that the invention is not limited to the embodiment described.

In particular, other liquid and gaseous components could be used.

1. A method of coating a substrate, said method being the type comprising:
placing said substrate in an enclosure under vacuum;
forming a gas by evaporating a component that is liquid at atmospheric pressure and at ambient temperature;
introducing said gas into said enclosure; and
decomposing said gas;
said method being characterized by introducing a complementary gas into said enclosure for the purpose of reacting with said decomposed gas so as to form, on said substrate, at least one thin layer, referred to as thin layer A.

2. The method of coating a substrate according to claim 1, in which said component is made up of organic and inorganic groups, e.g. of silicone.

3. The method of coating a substrate according to claim 1, in which said complementary gas is monomolecular up to at least 90%.

4. The method of coating a substrate according to claim 3, in which said complementary gas comprises, for the most part, either dioxygen, or argon, or dinitrogen, or dihydrogen, or acetylene.

5. The method of coating a substrate according to claim 1, in which said gas is decomposed with the help of electric plasma-creation means.

6. The method of coating a substrate according to claim 1, further comprising a step of forming another thin layer, referred to as a thin layer B, on said substrate, by vacuum deposition after or before forming said thin layer A.

7. The method of coating a substrate according to claim 6, in which said thin layers A and B are formed without extracting said substrate from said enclosure between forming each layer.

8. The method of coating a substrate according to claim 6, in which said thin layer A is formed after said thin layer B in such a manner as to cover said thin layer B, in particular in order to provide it with mechanical and/or chemical protection.

9. The method of coating a substrate according to claim 6, in which said thin layer B is formed after said thin layer A in such a manner that said thin layer A encourages smoothing said substrate and/or bonding said thin layer B.

10. The method of coating a substrate according to claim 6, in which said thin layer B is a layer of metalization.

11. The method of coating a substrate according to claim 10, in which said layer of metalization is formed by evaporating a solid component.

12. The method of coating a substrate according to claim 10, in which said layer of metalization is formed by evaporating an organometallic component that is in the liquid phase at ambient temperature and at atmospheric pressure.

13. A method of forming a colored film on a substrate, said method being the type in which at least two thin layers having different refractive indices are deposited on said substrate, said method being characterized in that at least one of said thin layers is obtained by a coating method according to claim 1.

14. The device for implementing a method of coating a substrate according to claim 1, said device comprising:
an enclosure for housing said substrate;
a tank external to said enclosure for containing a liquid component;
first admission means for admitting a gas into said enclosure and comprising means for connecting said enclosure to a portion of said tank containing a vapor phase of the gas-forming liquid;
means for decomposing said gas; and
second admission means for admitting a complementary gas for reacting with said decomposed gas.

15. The coating device according to claim 14, in which said first admission means include means for adjusting the admission flow rate of said gas.

16. The coating device according to claim 14, further comprising means for creating a vacuum in said enclosure.

17. The coating device according to claim 14, in which the gas-decomposition means are electric means for generating a plasma inside said enclosure from said gas.

18. The method of coating a substrate according to claim 2, in which said complementary gas is monomolecular up to at least 90%.

19. The method of coating a substrate according to claim 2, in which said gas is decomposed with the help of electric plasma-creation means.

20. The method of coating a substrate according to claim 3, in which said gas is decomposed with the help of electric plasma-creation means.

21. The method of coating a substrate according to claim 4, in which said gas is decomposed with the help of electric plasma-creation means.

22. A method of coating a substrate, said method comprising the steps of:
placing said substrate in an enclosure under vacuum;
forming a gas by evaporating a component that is liquid at atmospheric pressure and at ambient temperature;
introducing said gas into said enclosure;
decomposing said gas; and
introducing a complementary gas into said enclosure for the purpose of reacting with a decomposed gas so as to form, on said substrate, at least one first thin layer.

23. The method of coating a substrate according to claim 22, further comprising a step of forming at least one second thin layer on said substrate, by vacuum deposition after or before forming said at least one first thin layer.

24. The method of coating a substrate according to claim 2, in which said at least one third thin layer is formed to cover said at least one second thin layer, in particular in order to provide it with mechanical and/or chemical protection.

25. The method of coating a substrate according to claim 1, wherein said method further comprises the step of depositing at least two thin layers having different refractive indices on said substrate to provide a colored film on said substrate.

26. A system for coating a substrate, said system comprising:
an enclosure for housing said substrate;
a tank in fluid communication with said enclosure for containing a liquid and for providing a gas from said liquid to said enclosure;
means for decomposing said gas after it is received in said enclosure from said tank; and
a complementary gas source in fluid communication with said enclosure for providing a complementary gas to said enclosure for reacting with said decomposed gas.

27. The system according to claim 26, wherein said means for decomposing said gas comprises electric means for generating a plasma inside said enclosure from said gas.
